(19) United States
(12) Patent Application Publication
(10) Pub. No.: US 2002/0003440 A1
(43) Pub. Date: Jan. 10, 2002

(54) Femtosecond kerr-lens mode locking with negative nonlinear phase shifts

(76) Inventors: L. J. Qian, Ithaca, NY (US); Xiang Liu, Ithaca, NY (US); Frank W. Wise, Ithaca, NY (US)

Correspondence Address: HARTER SECREST & EMERY, LLP, 1600 BAUSCH & LOMB PLACE, ROCHESTER, NY, 14604-2711, US

(21) Appl. No.: 09/760,989

(22) Filed: Jan. 16, 2001

Related U.S. Application Data
(60) Provisional application No. 60/175,872, filed on Jan. 13, 2000.

(51) Int. Cl. H03K 5/19; H03K 5/22

(52) U.S. Cl. 327/21; 327/69

(57) ABSTRACT

A Kerr-lens mode-locked Cr:fosterite laser 15 operated with negative nonlinear phase shift. The nonlinear phase shift is induced by the cascade x⁽²⁾ x⁽²⁾ process in a lithium triborate crystal. Employing the cascade process at large phase mismatch produces a nearly linear frequency chirp. Transform-limited pulses as short as 60 fs are generated with positive cavity dispersion.

This application claims priority under 35 USC 119(e) from Provisional Application Ser. No. 60/175,872 filed Jan. 13, 2000.

This research was supported by the National Institute of Health under award RR 10075 and by the National Science Foundation under award ECS-9612255.

### FIELD OF INVENTION

The field of ultrafast science has been revolutionized by the development of Kerr-lens mode locking^{1,2} (KLM) in solid-state lasers. KLM is based on the nonresonant Kerr nonlinearity, and for almost all materials the nonlinear index n₂ (and thus the nonlinear phase shift ΔΦ^{NL}) is positive. In solitonlike pulse shaping, the frequency chirp induced by the positive nonlinearity is balanced by negative group-velocity dispersion (GVD), and prism pairs and chirped mirrors were developed to produce this balance. The signs of the nonlinearity and dispersion can be interchanged (FIG. 1), so if media with fast negative nonlinear refraction (i.e., self-defocusing) could be found, lasers could be operated with positive cavity dispersion. In either case some amplitude modulation is needed to stabilize the pulse formation. Operation at positive dispersion could simplify the design of compact and robust femtosecond lasers for applications.

Recently there has been a resurgence of interest in the effective third-order nonlinearity that arises from the cascading of χ⁽²⁾ processes. The renewed interest is based on the recognition that large effective third-order nonlinearities of controllable sign can be produced in the cascade process. Bakker and co-workers performed a systematic theoretical study of the phase shifts generated by three-wave interactions.³ Large cascade nonlinear phase shifts were later measured in potassium titanyl phosphate.⁴ Applications of the cascade nonlinearity include the mode locking of lasers, and this has been proposed and demonstrated.⁵ Pulses of ˜40-ps duration were generated; in this case the signs of ΔΦ^{NL} and cavity GVD have little influence on pulse shaping and laser performance.

Difficulties that must be addressed for the use of the cascade nonlinearity on a femtosecond time scale have been noted by previous workers. ΔΦ^{NL} is proportional to conversion efficiency η, and in general it is difficult to attain high efficiency in second-harmonic generation (SHG) with femtosecond pulses if the harmonic pulse is constrained to be no longer than the fundamental. Group-velocity mismatch (GVM) between the fundamental and the harmonic pulses and spatial walk-off will limit both conversion and backconversion efficiencies. These in turn limit the attainable nonlinear phase shift, and any residual second-harmonic light is a power-dependent loss that will destabilize KLM. A second complication is the fact that the phase shift produced by the cascade process can be modulated significantly owing to GVM.3,5,6 These issues have led some workers^{5,7} to conclude that it will be difficult to exploit the cascade nonlinearity with femtosecond-duration pulses.

### BRIEF DESCRIPTION OF THE INVENTION

Here we describe what is to our knowledge the first KLM laser operating with negative nonlinear phase shift. A lithium triborate (LBO) crystal inside a Cr:forsterite laser provides the effective nonlinearity by means of the cascade process. We believe that this is also the first application of the cascade process to mode locking with a broadband gain medium capable of supporting femtosecond pulses. We demonstrate that for a fairly large phase mismatch (Δ κL˜10π) the frequency chirp generated in the femtosecond cascade process is approximately linear over the center of the pulse, similar to that produced by the electronic Kerr effect. The laser performs as expected theoretically, and nearly transform-limited pulses as short as 60 fs are generated without a prism pair in the cavity.

We have analyzed the cascade process including the effects of GVM and the ordinary Kerr nonlinearity, which are essential to accurate modeling of the propagation of femtosecond pulses. Numerical solutions of the coupled wave equations allow us to evaluate the cascade process for application in femtosecond KLM lasers. We find that the deleterious effects of saturation of the cascade process and GVM on the phase shift of the fundamental pulse can be reduced substantially by using the cascade process at fairly large phase mismatch, ΔkL>˜6π. Although the magnitude of the cascade phase shift decreases with ΔkL, the decrease is naturally not so large if the cascade phase shift is saturating at lower ΔkL. This is the case in the KLM Cr:forsterite laser that was demonstrated experimentally. Finally, we define a figure of merit that can be used to guide the development of other femtosecond lasers mode-locked using the cascade process.

### BRIEF DESCRIPTION OF THE DRAWING

FIGS. 1a and 1b are block diagrams of femtosecond KLM lasers: (a) traditional approach, (b) approach described here.

FIG. 2. is a graph showing frequency sweeps generated in the cascade process with GVM equal to the pulse duration and Δ κL=2π and Δ κL=11π. The magnitude of the phase shift produced with Δ κL=2π is ˜2.5 times as large as that produced with Δ κL=11π. The fine solid curve corresponds to an instantaneous nonlinear index of refraction.

FIG. 3 is a schematic of the laser: dashed lines, beam path with prisms in the cavity; solid lines, paths without prisms. SESAM, semiconductor saturable absorber mirror.

FIG. 4 is a graph of pulse duration plotted versus cavity dispersion. Open symbols, ordinary KLM; filled symbols, KLM with the cascade nonlinearity. The curves are to guide the eye, and dashed portions of the curves indicate unstable regions.

FIG. 5 is a graph of autocorrelation and power spectrum (inset) of pulses generated with prisms removed from the laser. The time-bandwidth product is τΔν=0.4.

FIG. 6 is a table of the figures of merit for several important combinations of materials and wavelengths

FIG. 7 shows the conversion efficiency versus nonlinear drive for different values of ΔkL that satisfy the condition for minimum SHG efficiency

FIG. 8 shows associated peak nonlinear phase shifts

FIG. 9 shows the net nonlinear phase shifts obtained with the same drive (Γ²L²=22) and ΔkL (6.6π) but different intensities

FIGS. 10-15 show the results of the numerical simulations

FIG. 16 shows the temporal profile of the net nonlinear phase shift of a 60-fs pulse after a single pass of the LBO crystal

### DETAILED DESCRIPTION OF THE INVENTION

DeSalvo et al. showed⁴ that, for large phase mismatch Δ κL or low intensity or both, the nonlinear phase shift produced in the cascade process is approximately

ΔΦ^{NL}≈Γ²L²/Δ κL, (1)

where Γ=(ωd_{eff}|E₀|)/(c\sqrt{n2wnw}), E₀ is the incident fundamental field, and Δ κ=κ^{2ω}−2κ^{ω} This is the result of a plane-wave analysis that neglects (in addition to saturation of the cascade process) the effects of GVM, which are generally significant for femtosecond pulses.

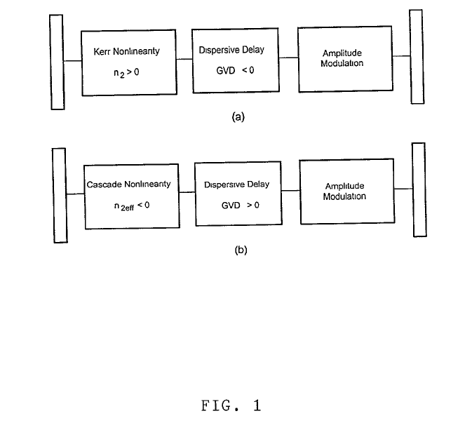

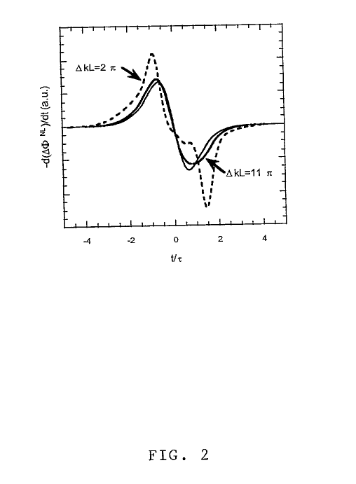

FIGS. 1a and 1b are block diagrams of femtosecond KLM lasers: (a) traditional approach, (b) approach described here.

It is clear that highly efficient SHG is required for generation of a phase shift that will be useful for KLM. We recently showed that the GVM for frequency doubling 1.3-μm light is small in LBO, and because the phase matching is nearly noncritical the acceptance angles are large and the spatial walk-off is small. These properties allowed us to demonstrate 44%-efficient frequency doubling of 3-nJ pulses as short as 50 fs from a mode-locked Cr:forsterite laser⁸ and are favorable for intracavity SHG.

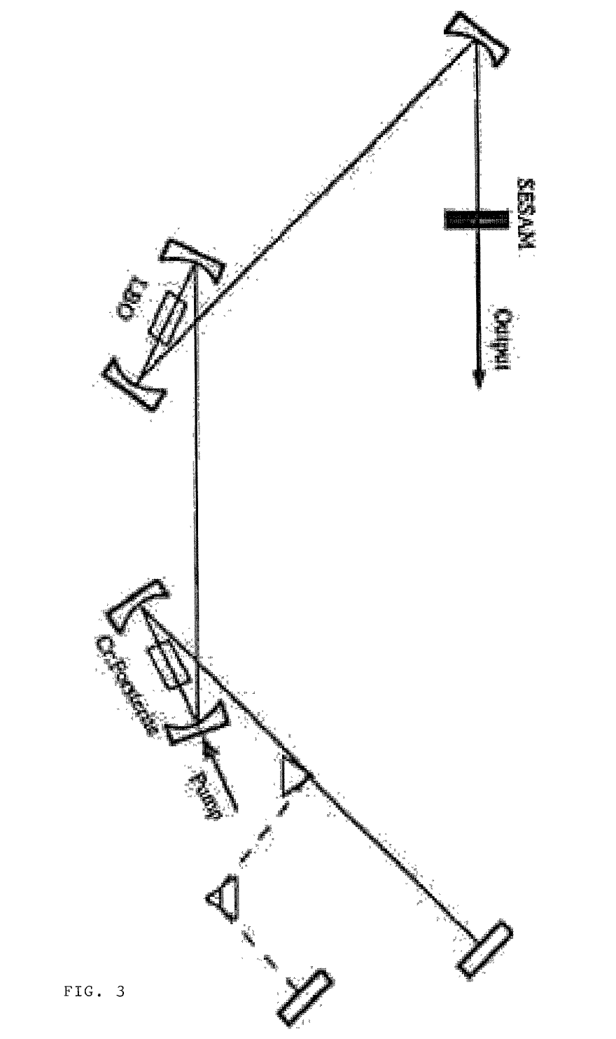

The simplified analysis of Ref. 4 is adequate for estimation of the magnitude of the cascade phase shift inside a femtosecond laser. We assume that the pulse energy will be a factor of 30 higher than as given in Ref. 8. With 100-fs pulses of 100-nj energy and an 8-mm LBO crystal the analysis of Ref. 4 predicts that ΔΦ^{NL} (cascade)≈1.5 rad with Δ κL≈2π. The Kerr nonlinearity in the doubling crystal contributes ΔΦ^{NL}≈+0.3 rad, for a net phase shift ΔΦ^{NL}≈−1.2 rad. We have solved the coupled-wave equations for pulse propagation in the SHG crystal numerically, including GVM and intensity-dependent phase matching. The numerical solutions show that for Δ κL≧6π the simplified analysis accurately predicts the magnitude of ΔΦ^{NL} if the GVM is not larger than the pulse duration. The temporal evolution of ΔΦ^{NL} is generally distorted, so the frequency chirp across the pulse is nonlinear. However, for Δ κL≧6π the phase follows the pulse intensity envelope nearly ideally, as is illustrated in FIG. 2. |ΔΦ^{NL}| decreases slowly with Δ κL, so little penalty is incurred by operating at large phase mismatch, where the frequency chirp is more desirable for KLM.

We used spectrally resolved two-beam coupling⁹ to measure the electronic Kerr nonlinearities of LBO and Cr:forsterite and found that n₂(Cr:forsterite)=2×10⁻¹⁶ cm^{2/}W and n₂(LBO)=1.4n₂(Cr:forsterite). Measurement of a 0.5-mm length of LBO with Δ κL≧2π shows that ΔΦ^{NL} is negative and larger in magnitude than the nonlinear phase shift in a similar length of Cr:forsterite. If we assume theoretical scaling with length, we conclude that |ΔΦ^{NL}| produced by the 8-mm LBO crystal should be adequate to produce a net negative nonlinear phase shift in a Cr:forsterite laser for Δ κL in the range 2π-20π. Direct measurements of ΔΦ^{NL} versus Δ κL in the long crystal will be valuable, but the 1.3-μm pulse energies required for Z-scan measurements⁴ are currently not available in our laboratory.

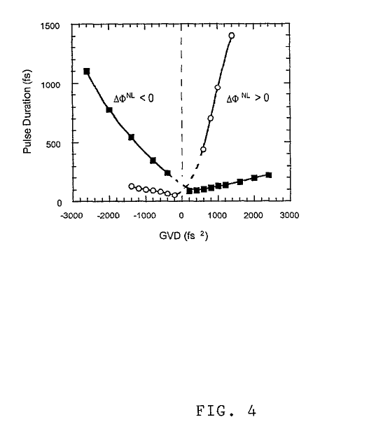

FIG. 3 shows a laser designed to operate with ΔΦ^{NL}<0 A fold for the SHG crystal is added to an ordinary Cr:forsterite laser.¹⁰ The gain and SHG crystals are both 8-mm long. Mirrors with 10-cm radii of curvature are used in both folds, and the gain end of the cavity is imaged onto the SHG end such that conditions in the gain medium do not change with the addition of the SHG crystal. The repetition rate of the laser is 50 MHz. The GVD of the gain crystal is 400 fs², and that of the LBO crystal is −90 fs² at 1.27 μm. A pair of SF-6 prisms is set to permit variation of the cavity GVD from −3000 to +2500 fs², and a semiconductor saturable-absorber mirror¹¹ is used to start the mode-locking process while providing ˜1% output coupling.

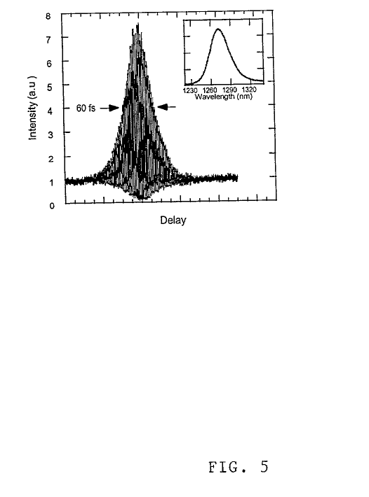

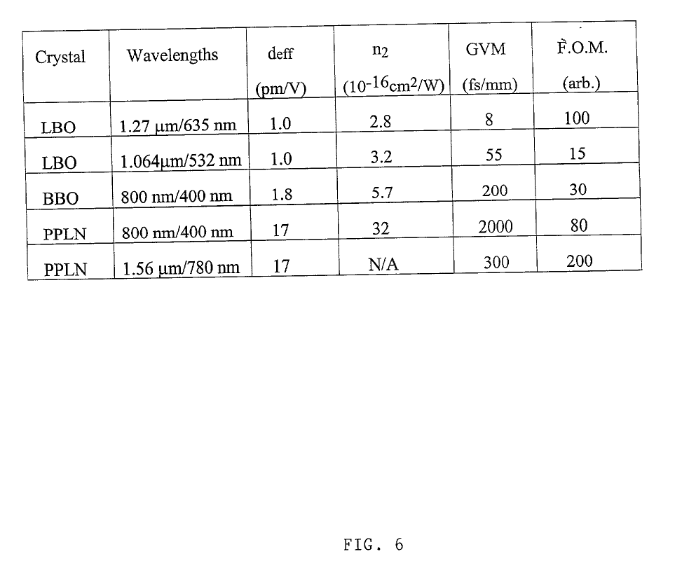

As a control experiment we translated the LBO crystal away from the beam waist and obtained normal KLM operation. The dependence of pulse duration τ on cavity GVD is plotted as open symbols in FIG. 4. From the slope of the graph at GVD<0 we estimate the (round-trip) nonlinear phase shift ΔΦ^{NL}≈0.4 rad, and this agrees with both the value measured similarly for previous Cr:forsterite lasers and the value calculated by use of the measured n₂(Cr:forsterite) and the experimental intensity.

With the LBO crystal at the focus of the second fold, stable mode-locked pulse trains are generated in the range 6π<Δ κL<16π. The broadest fundamental spectrum occurs with Δ κL≈10π. With Δ κL fixed at this value, the pulse duration depends on GVD, as shown by the filled symbols in FIG. 4. Qualitatively, the trend is the reflection of normal KLM behavior about GVD=0, as expected for ΔΦ^{NL}<0. This includes the observation of an unstable region about GVD=0, indicated by the dashed portions of the curves in FIG. 4. The time-bandwidth product is always less than 0.4 (a sech pulse shape is assumed) for ΔΦ^{NL}<0 and GVD>0. From the slope of the graph at positive dispersion we infer that ΔΦ^{NL}(total)≈−0.4 rad, which allows us to estimate ΔΦ^{NL} produced by the cascade process:

ΔΦ^{NL}(cascade)=ΔΦ^{NL}(total) −ΔΦ^{NL}(Cr:forsterite, Kerr) −ΔΦ^{NL}(LBO, Kerr) ≈−0.4−0.4−0.6≈−1.4 rad.

The single-pass nonlinear phase shift generated in the cascade process is therefore −0.7 rad. This number agrees reasonably well with the value −0.6 rad calculated numerically or estimated from relation (I) with the experimental drive Γ²L²≈18.

We also obtain stable mode locking with Δ κL≈−2π, where ΔΦ^{NL}(cascade) is theoretically positive and near its maximum value. With positive GVD a narrow spectrum and long, highly chirped pulses are indeed observed, as expected for ΔΦ^{NL}>0 and GVD>0.^{2,12}

The broad bandwidth of the femtosecond pulses precludes perfect backconversion to the fundamental, and the residual second harmonic constitutes a nonlinear loss that works to destabilize KLM. From the generated harmonic beam we estimate the nonlinear loss that is due to SHG as 1%. This amount of loss is just accommodated with the saturable-absorber mirror, which provides a fractional reflectivity increase of 0.8% at the intracavity pulse intensity. The laser is self-starting, but marginally so. If we adjust Δ κL to reduce the conversion efficiency, completely reliable self-starting operation is obtained.

The generation of transform-limited pulses in cavities with positive GVD potentially simplifies the design of mode-locked lasers. With the prism pair removed from the laser, the cavity dispersion is +310 fs². Under these conditions we observe transform-limited pulses as short as 60 fs (FIG. 5). In this demonstration the benefit of removing the prisms is offset by the addition of the second fold, but adding that fold may not be essential.

Finally, the laser is stable and already offers useful performance. Energies of ˜1 nJ are available for the shortest pulses, although the output power has not been optimized. The residual second-harmonic pulses have similar energy and should be useful either by themselves or in applications that need synchronized femtosecond pulses at 1270 and 635 nm. With Δ κL≈6π, 130-fs pulses with 2-nJ energy are generated, but the harmonic pulse energy decreases to 0.2-nJ.

It has been realized that the cascading of χ⁽²⁾(ω;2ω,−ω) and χ⁽²⁾(2ω;ω,ω) processes leads to a nonlinear phase shift (ΔΩ^{NL}) in a pulse that traverses a quadratic nonlinear medium under phase-mismatched conditions for second harmonic generation (SHG) or parametric processes [1]. Bakker and co-workers performed a systematic theoretical study of the phase shifts generated by three-wave interactions [2]. Large cascade nonlinear phase shifts were later measured in KTP [3,4] and periodically poled LiNbO₃ (PPLN) [5], and the phase shifts could be either positive or negative, depending on the sign of the phase mismatch. For these materials the effective nonlinear indices can be two to three orders of magnitude larger than the Kerr nonlinear index (n₂) of fused silica. The nonlinear phase shifts generated in the cascade process have been applied to optical switching [6] and soliton formation [7]. In the ultrafast laser field, it is desirable to find large cubic nonlinearities that could provide the phase modulation needed for Kerr-lens mode-locking (KLM). Recently, Zavelani-Rossi et al. [8] demonstrated the mode-locking of a picosecond Nd:YAG laser by the use of large positive cascaded nonlinear phase shifts accumulated in a LiB₃O₅ (LBO) crystal.

On the femtosecond time scale, the generation of nonlinear phase shifts by the cascade process inevitably meets a number of difficulties common to efficient frequency-doubling of ultrashort pulses, including group-velocity mismatch (GVM) and bandwidth limitations. Previous workers have shown that the cascade phase shift can be severely modulated owing to GVM [9-11]. To generate a large nonlinear phase shift, the drive

$$( {Γ}^{2} {L}^{2} , with Γ = \frac{ω {d}_{eff} \vert {E}_{0} \vert}{c \sqrt{{n}_{2 ω} {n}_{ω}}} )$$

[12] of the SHG process must be large and hence the Kerr nonlinearity (χ⁽³⁾) itself will contribute significantly to the net phase shift. In this paper, we report an investigation of the phase shifts accumulated by femtosecond-duration pulses undergoing the cascade process with type-I phase-matching. This investigation is motivated by the possible application of the cascade process to Kerr-lens mode-locking, and our evaluation of the produced nonlinear phase shifts will be in that context. The Kerr nonlinearity, GVM, and intra-pulse group-velocity dispersion (GVD) are included in the analysis. The coupled equations governing the cascade process are solved numerically, and the effects of GVM, the Kerr nonlinearity, and phase-mismatch ΔkL on the resulting nonlinear phase shifts are presented. Based on the computer simulations, we propose guidelines for producing large nonlinear phase shifts with temporal variations that are useful for pulse shaping and compression. For the present purposes we define the ideal nonlinear phase shift as that directly proportional to the pulse intensity, as would be produced by the Kerr nonlinearity with an instantaneous response. This corresponds to an approximately linear frequency chirp across the center of the pulse. Considering the quality of the phase shift relative to this ideal, we define a figure-of-merit (FOM) for using the cascade process on the femtosecond time scale. In particular, we find that there are advantages to working at relatively large ΔkL: saturation of the magnitude of ΔΦ^{NL} and distortion due to saturation and GVM are weaker than at small ΔkL. Finally, the calculations show that under optimized conditions, large negative nonlinear phase shifts are obtainable with sub-100-fs laser pulses through the cascade process in an LBO crystal at wavelengths near 1.3 μm. The theoretical results agree well with our recent experimental demonstration of a femtosecond Kerr-lens mode-locked Cr:forsterite laser with ΔΦ^{NL}<0[14].

Theoretical Basis of the Calculations

Starting from Maxwell equations and using the slowly varying envelope approximation, we write the general coupled equations governing the cascade process in the frame moving with the fundamental wave as [13]

$$\begin{matrix}( \frac{\partial }{\partial z} + \frac{{iz}_{I}}{4 {l}_{d1}} \frac{{\partial }^{2}}{\partial {t}^{2}} ) {E}_{1} = {iE}_{1}^{*} {E}_{2} {e}^{i Δkz} + i2 π ( {n}_{2} {I}_{0} ) \frac{{z}_{I}}{λ} [ {\vert {E}_{1} \vert}^{2} + 2 {\vert {E}_{2} \vert}^{2} ] {E}_{1} , & ( 1 ) \\ ( \frac{\partial }{\partial z} + \frac{{l}_{I}}{{l}_{W}} \frac{\partial }{\partial t} + \frac{{iz}_{I}}{4 {l}_{d2}} \frac{{\partial }^{2}}{\partial {t}^{2}} ) {E}_{2} = {iE}_{1} {E}_{1} {e}^{- i Δkz} \frac{{n}_{ω}}{{n}_{2 ω}} + i4 π ( {n}_{2} {I}_{0} ) \frac{{z}_{I}}{λ} \frac{{n}_{ω}}{{n}_{2 ω}} [ 2 {\vert {E}_{1} \vert}^{2} + {\vert {E}_{2} \vert}^{2} ] {E}_{2} , & ( 2 )\end{matrix}$$

where E₁ and E₂ are the normalized (by the peak value of the initial fundamental wave, E₁₀) amplitudes of the fundamental and harmonic fields, respectively. Δk=k_{2ω}−2k_{ω} is the (type-I) phase-mismatch between the two waves, and n₂ is the Kerr nonlinearity (its dispersion is neglected). The normalizing interaction length z_{I}=2n_{ω}c/(ω_{χ}⁽²⁾E₁₀), and the propagation length z is normalized to z_{I}. The temporal walk-off length l_{w}=cτ/(n_{1g}−n_{2g}) with τ the initial fundamental pulse duration and n_{ig} the group index at frequency i, and the dispersion length is defined as

$${I}_{d} = {τ}^{2} / ( 4 g ) where g = \frac{1}{2} \frac{{\partial }^{2} k}{\partial {ω}^{2}}$$

is the dispersion coefficient.

DeSalvo et al. [3] solved the coupled equations neglecting the Kerr nonlinearity and GVM. With the additional assumptions of large phase mismatch and/or low intensity, the nonlinear phase shift of the fundamental pulse is approximately

ΔΦ^{NL}≈−Γ²L²/ΔKL. (3)

To obtain exact solutions of the coupled propagation equations, we use a symmetric split-step beam-propagation method. We use a fourth-order Runge-Kutta algorithm to solve the nonlinear part in the time domain, and solve the dispersion part in the frequency domain after a Fourier transform. The propagation in each step has the symmetric form as described previously [13]. This implementation is numerically efficient, with accuracy to third order in the step size. The amplitude of the initial fundamental pulse has the form E₁₀sech(t/τ), which is the soliton solution of Kerr-lens mode-locked lasers.

Numerical Simulations and Discussion

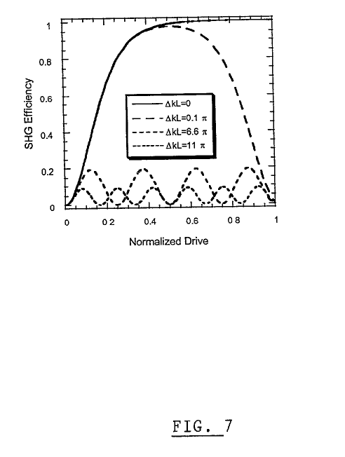

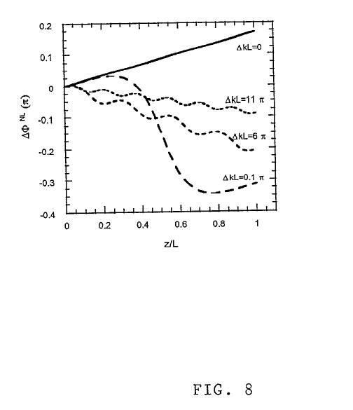

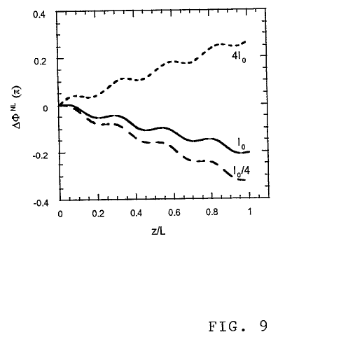

As noted by Stegeman et al. [4], in some applications it will be advantageous to minimize the SHG, which acts as a loss for the fundamental pulse. For low nonlinear drive, the minimum loss occurs at ΔkL=2nπ, where n is an integer. This simple result breaks down when the drive is large, however. FIG. 7 shows the conversion efficiency versus nonlinear drive for different values of ΔkL that satisfy the condition for minimum SHG efficiency. The parameters used in the simulation are Γ²L²=22(the x-axis is normalized to this value), I₀=80 GW/cm², d_{eff}=1 pm/V, L=5 mm, and λ₁=1.27 μm. The measured nonlinear index (n₂=2.8×10⁻¹⁶ cm²/W) of LBO is assumed in the calculations. The first loss minimum occurs at ΔkL=0.1π, compared to 2π in the low-drive limit. The associated peak nonlinear phase shifts are shown in FIG. 8. With ΔkL=0, there is no cascade phase shift, so ΔΦ^{NL} increases linearly with length due to the Kerr nonlinearity. With ΔkL=0.1π, ΔΦ^{NL} is maximum, but it exhibits a stepwise behavior, similar to the results of Stegeman et al. [4]. The “steps” are not flat in this case, owing to the inclusion of the Kerr nonlinearity. This stepwise behavior is undesirable since it leads to distortion of the nonlinear phase shift. With the increase of ΔkL, ΔΦ^{NL} becomes more linear with length. At ΔkL=6.6π, the fluctuations around the linear overall trend are <π/50, similar to the phase distortion experienced by a beam reflected by a mirror surface with a roughness of <λ/100. The important implication is that under conditions of large drive it is beneficial to work at large ΔkL values, so that saturation of the nonlinear phase shift is reduced. For instance, at ΔkL=2π, the nonlinear phase shift due to the cascade nonlinearity alone is ˜−1.5 rad while the unsaturated value is ˜−4 rad. In contrast, at ΔkL=6.6π the cascade nonlinear phase shift is ˜−1.1 rad, close to the unsaturated value of −1.2 rad. Equation (3) provides an upper limit on the phase shift, and at sufficiently large ΔkL values (ΔkL>˜Γ²L²), this upper limit gives a fairly good approximation to the actual nonlinear phase shift. It is also worth noting that under the conditions assumed in the calculations, the cascade and Kerr processes are not strongly coupled. This means that the cascade process is not strongly affected by intensity-dependent phase-matching of the SHG process. Under the conditions assumed in FIG. 7, the overall nonlinear phase shift accumulated by a pulse is approximately (to within 30%) the linear sum of the cascade phase shift and that due to the Kerr nonlinearity.

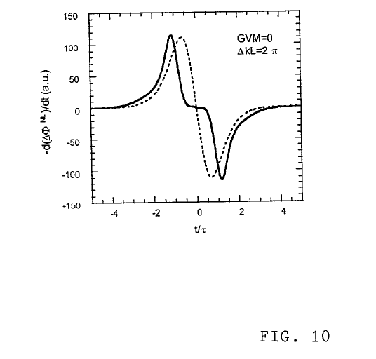

For applications in mode-locking of lasers, a large negative ΔΦ^{NL} would be desirable. From Equation (3), we see that the magnitude of the cascade phase shift increases approximately as L² with fixed ΔkL. This is countered by the linear dependence of the phase shift due to the Kerr nonlinearity. Therefore, it is possible to increase the net negative nonlinear phase shift (for fixed nonlinear drive) by using longer propagation lengths. This can also be seen in the coupled equations (1) and (2). If the drive is fixed, the use of a longer crystal or a material with larger d_{eff} reduces the required pump intensity I₀, which in turn reduces the relative contribution of the Kerr nonlinearity. FIG. 9 shows the net nonlinear phase shifts obtained with the same drive (Γ²L²=22) and ΔkL (6.6π) but different intensities. The solid line in FIG. 9 corresponds to the same conditions as in FIG. 7. With the intensity reduced by a factor of four (I₀/4), the net negative nonlinear phase shift increases in magnitude from −0.2π to −0.33π, a ˜50% improvement. With the intensity 4I₀, the contribution from the Kerr nonlinearity surpasses that from the cascade process, and the net phase shift is positive.

Previous work [9-11] has established that the phase shift generated in the cascade process can be distorted severely from the-ideal form by saturation and/or GVM. The generation of large phase shifts naturally requires working under conditions of some saturation. Furthermore, GVM is difficult to avoid with femtosecond-duration pulses. Thus, distortion of the phase shift becomes an imposing obstacle to application of the cascade process on the femtosecond time scale. Earlier reports do not propose solutions to this problem, other than the obvious one of reducing the GVM. However, it is reasonable to expect the deleterious effects of GVM to be suppressed to some extent when the cascade phase shift is produced at large phase mismatch. When ΔkL is large, the fundamental pulse experiences nearly complete back-conversion several times as it traverses the crystal. Each cycle of conversion and back-conversion defines an effective interaction length that is shorter than the overall interaction length, and the effects of GVM accumulated over the effective interaction length are therefore smaller than would be the case if the interaction length were the overall crystal length. Distortion of the phase shift or frequency chirp should be less than at small ΔkL, where there are fewer conversion cycles and thus the effective interaction length is greater. A similar argument can be made in the frequency domain. We define an acceptance bandwidth Δω within which the variation of ΔΦ^{NL} is limited to a percentage of its average value. From Equation (3) we find that Δω∝ΔkL/GVM. This acceptance bandwidth should be contrasted with the well-known phase-matching bandwidth for the SHG process, which depends only on the GVM.

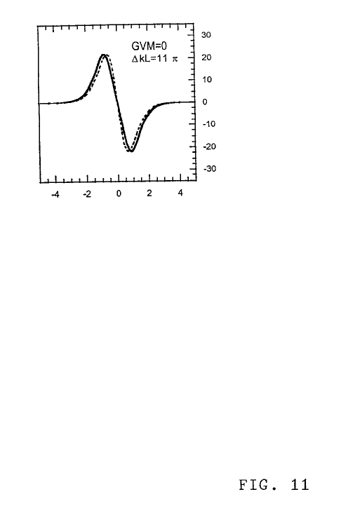

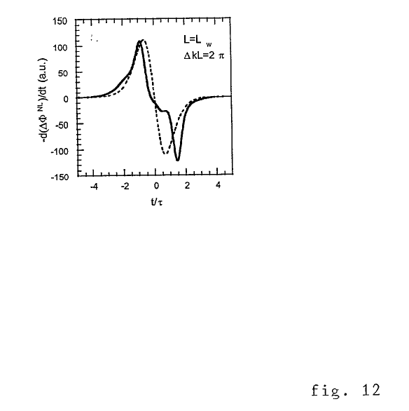

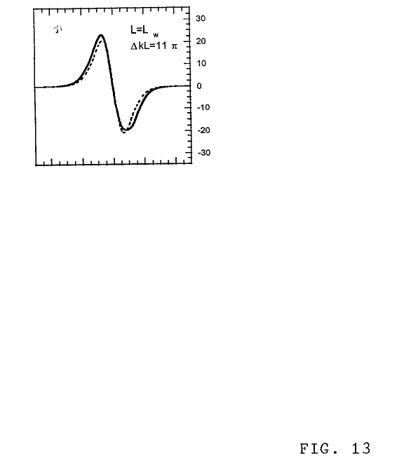

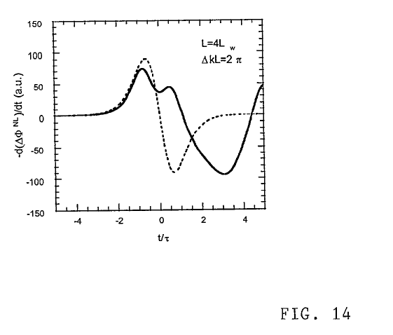

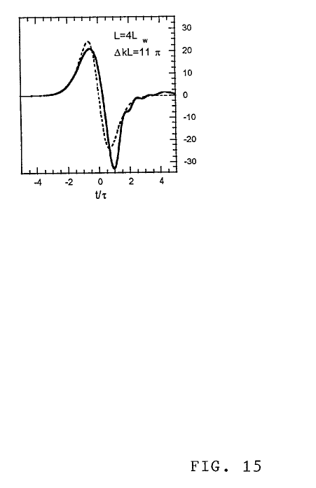

Numerical calculations were performed with different values of the temporal walk-off length L_{w} and phase mismatch ΔkL to determine if nonlinear phase shifts with acceptably little distortion can be generated. The results of the numerical simulations are summarized in FIGS. 10 11 12 13 14 and 15. The dotted line in each figure represents the ideal chirp on the sech² pulse. FIGS. 10 and 11 show the case with GVM=0. The center portion of the chirp profile is severely distorted at ΔkL=2π, while the distortion is much less severe at ΔkL=11π. In this case the improvement is the result of reducing the saturation. In exchange for the improved frequency sweep, the magnitude of the cascade phase shift is reduced by a factor of 2.5. With small GVM (the crystal length L is equal to the temporal walk-off length L_{w}) and ΔkL=2π(FIG. 12), the chirp is shifted and becomes asymmetric due to the slower group velocity of the second-harmonic pulse. Interestingly, with ΔkL=11π(FIG. 13), the chirp is quite close to the ideal shape. Large GVM (L=4L_{w}) severely shifts and distorts the phase shift generated at ΔkL=2π(FIG. 14. Even in this extreme case, substantial improvement is obtained at ΔkL=11π(FIG. 15). The chirp is shifted, but is close to linear over a large portion of the pulse.

The traces of FIGS. 10-15 explicitly demonstrate the advantages of using the cascade process at large ΔkL: the phase distortions due to saturation and GVM are substantially reduced. The generated chirp is more linear across the center of the pulse, where most of the energy resides, with large ΔkL. It is reasonable to conclude that at adequately large ΔkL, the cascade nonlinearity can be used for shaping femtosecond pulses as short as the walk-off time in the nonlinear medium. In contrast, previous workers found that for ΔkL=π[8], the effect of GVM is a limiting factor of pulse shortening even when temporal walk-off time is 10 times shorter than the pulse duration. They demonstrated that with the introduction of GVM compensation, the pulse duration could be further shortened by a factor of 2.

Specific Applications

To compare some practically-interesting applications of the cascade phase shift on the femtosecond time scale, we can define a figure of merit. With a given incident pulse energy E, we write:

$$Δ {Φ}^{NL} \approx - \frac{{Γ}^{2} {L}^{2}}{Δ kL} ∝ E \cdot \frac{{d}_{eff}^{2} {ω}^{2}}{{n}_{ω}^{3} \cdot GVM} = E \cdot FOM , \qquad ( 4 )$$

where FOM is the figure of merit and GVM has units of fs/mm. The optimal-focusing condition for Gaussian beams is assumed in the expression for FOM. The figures of merit for several important combinations of materials and wavelengths are shown in Table 1. Fixed values of pulse duration and large ΔkL are assumed. We normalize the FOM by defining the cascade process in LBO with λ=1.27 μm to have FOM=100. The figure of merit only considers the phase shift generated in the cascade process. The Kerr nonlinearity will produce a positive phase shift, and so must also be considered in the evaluation of materials for applications that require ΔΦ^{NL}<0. Finally, actual applications will also depend on the available pulse energy. The figures of merit for several important combinations of materials and wavelengths are shown in Table 1.

The first line in the table corresponds to the KLM Cr:forsterite laser successfully operated with ΔΦ^{NL}<0 [12]. The second line in the table considers mode-locking of a Nd:YAG laser using the cascade nonlinearity. With large pulse energies, it is possible to obtain large cascade nonlinear phase shifts as demonstrated with picosecond pulses [8]. The third and forth items in the table address the possibility of operating a KLM Ti:sapphire laser based on the cascade phase shift. The prospects are not very good using a standard barium metaborate (BBO) crystal, owing to the relatively large GVM of BBO for 800 nm→400 nm SHG. Although the GVM of PPLN is even larger, this is more than offset by its large value of d_{eff}². A femtosecond Ti:sapphire laser mode-locked using the cascade process appears to be possible, although a practical difficulty is that PPLN poled with the short period (˜2.5 μm) required for this SHG process is not commercially available yet. The last item in the table is aimed at the problem of excessive nonlinear phase shifts, which typically limit the pulse energy in fiber lasers. A negative phase shift produced by the cascade process could be used to reduce the net phase shift accumulated by the pulse in a fiber laser.

Comparison with Experimental Results

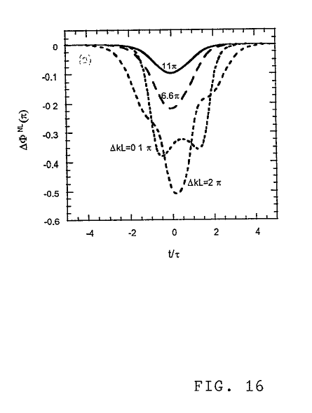

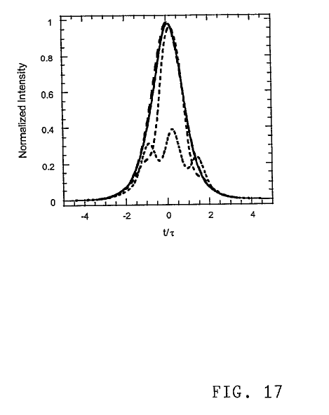

We recently demonstrated Kerr-lens mode-locking of a Cr:forsterite laser with negative nonlinear phase shifts produced by the cascade process in an LBO crystal [14]. Pulses as short as 60 fs are obtained with phase mismatch in the range 6π<ΔkL<16π. We performed simulations with the known experimental conditions: λ₁=1.27 μm, GVM=8 fs/mm, L=5 mm (the actual crystal length is 8 mm, but the confocal parameter of the cavity mode is ˜1 mm, so the interaction length is shorter than the crystal length), I=80 GW/cm², and n₂(LBO) as given in Table 1. The temporal profile of the net nonlinear phase shift of a 60-fs pulse after a single pass of the LBO crystal is shown in FIG. 16 for several different values of ΔkL. To illustrate the effects of the generated phase shifts, we show in FIG. 17 the pulse shapes calculated assuming those phase shifts. It is evident that with ΔkL=6.6π, the nonlinear phase shift is minimally distorted, and the fundamental pulse is nearly fully recovered (<2% loss to SHG). The round-trip nonlinear phase shift averaged over the pulse is ΔΦ^{NL}(LBO)=−1.2 rad. This value agrees well with the nonlinear phase shift estimated from a measurement of n_{2eff} of the LBO crystal by spectrally-resolved two-beam coupling [15]. The positive Kerr nonlinearity of the Cr:forsterite gain crystal produces ΔΦ^{NL}(forsterite) [symbol] 0.4 rad, so the overall phase shift accumulated by the pulse in the cavity is negative. With ΔkL=9π(not shown) and 11π, the fundamental pulse is also nearly fully recovered, and the net nonlinear phase shifts are −0.9 and −0.6 rad, respectively. However, with smaller ΔkL, the fundamental pulse is not fully recovered in terms of temporal shape and energy. These results are completely consistent with the performance of the KLM Cr:forsterite laser. We find stable Kerr-lens mode-locking with ΔΦ^{NL}<0 (this can be inferred from measurements of the pulse duration versus cavity dispersion) for phase mismatch in the range 6π<ΔkL<16π. Transform-limited pulses as short as 60 fs are generated with positive cavity dispersion. The laser adjusts the operating conditions to minimize the loss due to SHG in this range. The residual harmonic pulses are nearly transform-limited and 100 fs in duration, with pulse energies ranging from 0.1 to 1 nJ depending on the phase-mismatch. When ΔkL is decreased to below 6π, modelocking begins to exhibit instabilities. With further reduction of ΔkL highly chirped pulses are generated, and eventually mode-locking stops. As ΔkL is reduced, the magnitude of ΔΦ^{NL} increases, but the phase shift becomes more distorted. The distortions of the phase shift cannot be compensated by ordinary second-order dispersion, so the generated pulse has phase distortions across its spectrum and thus deviates from the transform-limit. With enough distortion of the phase, stable modelocking cannot be achieved.

Although our primary focus is on the phase shift of the fundamental pulse, the cascade process produces a phase shift for the harmonic pulse as well. This has important consequences for applications in which the harmonic pulse is useful. For example, even the residual SHG that occurs in a laser mode-locked using the cascade process can be useful. We investigated the characteristics of the generated second-harmonic pulses for conditions of nearly minimum conversion efficiency, and found that the temporal shape of the harmonic pulse is quite sensitive to the amount of the phase-mismatch. Usually the pulse shapes are irregular, but a gaussian-like pulse shape can be obtained. On the other hand, the spectrum of the harmonic pulses is always a single peak without structure. Experimentally, we observe nearly-transform-limited sub-100-fs second-harmonic pulses associated with the 60-fs fundamental pulses.

We have demonstrated the operation of a KLM laser in which the nonlinear phase shift is negative. Crucial in this development is the recognition that undistorted phase shifts can be generated by the cascade process at large values of Δ κL. The laser's performance agrees qualitatively with the theory of KLM, and pulses as short as 60 fs are generated with positive cavity dispersion. This approach allows us to envisage simple, compact femtosecond lasers consisting of gain and second-harmonic crystals in a single confocal cavity with ordinary laser mirrors.

While the inventor has described in connection with a presently preferred embodiment thereof, those skilled in the art will recognize that certain modifications and changes may be made therein without departing from the true spirit and scope of the invention which is intended to be defined solely by the appended claims.

We claim:

1. A method of generating pulses of sub-picosecond duration from a laser comprising;
pumping a gain medium to provide stimulated emission therefrom;
resonating the stimulated emission to provide amplification thereof and produce a light beam;
producing a negative nonlinear phase shift by use of cascaded second-order (χ⁽²⁾) nonlinear processes,
compensating the negative phase shift with normal group-velocity dispersion to generate the sub-picosecond pulses.

2. The method of claim 1 in which the step of producing the negative non-linear phase shift comprises passing the beam of light through a crystal.

3. The method of claim 1 in which the step of pumping a gain medium comprises pumping a solid-state material.

4. The method of claim 3 in which the gain medium is a fiber.

5. A laser producing sub-picosecond pulses comprising:
a gain medium with positive group velocity dispersion,
a second order non-linear medium providing a negative phase shift generated by the cascading of chi-2 processes,
wherein the positive group-velocity dispersion in the gain medium at least partially compensates for the negative phase shift produced by the second order nonlinear medium to generate a short pulse.

6. The laser of claim 5 in which the medium producing the negative phase shift is a crystal.

7. The laser of claim 1 in which the gain medium is a solid-state material.

8. The laser of claim 7 in which the gain medium is a fiber.
